(19) United States
(12) Patent Application Publication
(10) Pub. No.: US 2026/0369951 A1
(43) Pub. Date: Nov. 19, 2026

(54) GAS LASER DEVICE AND ELECTRONIC DEVICE MANUFACTURING METHOD

(71) Applicant: Gigaphoton Inc., Tochigi (JP)

(72) Inventors: Daiki MASUOKA, Tochigi (JP); Hirotaka MIYAMOTO, Tochigi (JP)

(73) Assignee: Gigaphoton Inc., Tochigi (JP)

(21) Appl. No.: 19/640,312

(22) Filed: Apr. 6, 2026

(30) Foreign Application Priority Data
May 16, 2025 (JP) 2025-082621

(51) Int. Cl. H01S 3/00; G02B 17/06; G03F 7/00; G03F 7/20; H01S 3/23

(52) U.S. Cl. CPC H01S 3/0057; G02B 17/0647; G03F 7/2004; G03F 7/70025; G03F 7/70041; H01S 3/2308

(57) ABSTRACT

A gas laser device includes a laser oscillator configured to output pulse laser light having an ultraviolet wavelength; a laser amplifier configured to amplify the pulse laser light output from the laser oscillator, and including an optical resonator including an output coupling mirror that outputs the amplified pulse laser light, and a laser chamber arranged on an optical path of the optical resonator and including a pair of discharge electrodes; a first beam expander arranged downstream of the laser chamber in an output direction of the pulse laser light and configured to expand a beam width of the pulse laser light output from the laser chamber; a second beam expander configured to further expand the beam width of the pulse laser light output from the first beam expander; and an optical pulse stretcher configured to extend a pulse width of the pulse laser light output from the second beam expander.

### CROSS-REFERENCE TO RELATED APPLICATIONS

The present application claims the benefit of Japanese Patent Application No. 2025-082621, filed on May 16, 2025, the entire contents of which are hereby incorporated by reference.

### BACKGROUND

### 1. Technical Field

The present disclosure relates to a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

Since excimer laser light output from a KrF excimer laser device or an ArF excimer laser device has a pulse width of several 10 ns and a wavelength thereof is short as about 248 nm or 193 nm, excimer laser light is sometimes used for direct processing of a polymer material, a glass material, or the like. Chemical bonds in polymeric materials can be broken by excimer laser light having a photon energy higher than the bond energy. Therefore, it is known that excimer laser light enables non-thermal processing of polymer materials, resulting in a clean processed shape. Further, it is known that, since glass, ceramics, and the like have high absorptance with respect to excimer laser light, even a material that is difficult to be processed with visible and infrared laser light can be processed with excimer laser light.

### LIST OF DOCUMENTS

### Patent Documents

Patent Document 1: US Patent Application Publication No. 2008/291962
Patent Document 2: International Publication No. WO2024/252498

Patent Document 3: Japanese Patent Application Publication No. H04-301613

### SUMMARY

A gas laser device according to an aspect of the present disclosure includes a laser oscillator configured to output pulse laser light having an ultraviolet wavelength; a laser amplifier configured to amplify the pulse laser light output from the laser oscillator, and including an optical resonator including an output coupling mirror configured to output the amplified pulse laser light, and a laser chamber arranged on an optical path of the optical resonator and including a pair of discharge electrodes; a first beam expander arranged downstream of the laser chamber in an output direction of the pulse laser light and configured to expand a beam width of the pulse laser light output from the laser chamber; a second beam expander configured to further expand the beam width of the pulse laser light output from the first beam expander; and an optical pulse stretcher configured to extend a pulse width of the pulse laser light output from the second beam expander.

An electronic device manufacturing method according to an aspect of the present disclosure includes generating pulse laser light using a gas laser device, outputting the pulse laser light to an exposure apparatus, and exposing a photosensitive substrate to the pulse laser light in the exposure apparatus to manufacture an electronic device. Here, the gas laser device includes a laser oscillator configured to output the pulse laser light having an ultraviolet wavelength; a laser amplifier configured to amplify the pulse laser light output from the laser oscillator, and including an optical resonator including an output coupling mirror configured to output the amplified pulse laser light, and a laser chamber arranged on an optical path of the optical resonator and including a pair of discharge electrodes; a first beam expander arranged downstream of the laser chamber in an output direction of the pulse laser light and configured to expand a beam width of the pulse laser light output from the laser chamber; a second beam expander configured to further expand the beam width of the pulse laser light output from the first beam expander; and an optical pulse stretcher configured to extend a pulse width of the pulse laser light output from the second beam expander.

### BRIEF DESCRIPTION OF THE DRAWINGS

Embodiments of the present disclosure will be described below merely as examples with reference to the accompanying drawings.

FIG. 1 shows the configuration of a gas laser device according to a comparative example.

FIG. 2 shows the configuration of a laser amplifier according to an improved configuration of the comparative example.

FIG. 3 shows the configuration of the laser amplifier according to the improved configuration of the comparative example.

FIG. 4 shows the configuration of the laser amplifier according to a first embodiment.

FIG. 5 shows the configuration of the laser amplifier according to the first embodiment.

FIG. 6 shows the configurations of the laser amplifier and a second beam expander according to a second embodiment.

FIG. 7 shows the configurations of the laser amplifier and the second beam expander according to the second embodiment.

FIG. 8 shows the configurations of the laser amplifier, a first beam expander, and the second beam expander according to a third embodiment.

FIG. 9 shows the configurations of the laser amplifier, the first beam expander, and the second beam expander according to the third embodiment.

FIG. 10 shows the configuration of an exposure system.

### DESCRIPTION OF EMBODIMENTS

### Contents

1. Comparative example
   1.1 Configuration of gas laser device 100
   1.2 Operation of gas laser device 100
2. Problem of comparative example
3. Laser amplifier PO including second beam expander 20
   3.1 Configuration
   3.2 Magnification ratio of beam width
   3.3 Shift of optical axis
   3.4 Inclination of optical axis
   3.5 Beam divergence angle
   3.6 Effect
4. Example of arranging second beam expander 20 outside optical resonator
   4.1 Configuration
   4.2 Effect
5. Example of arranging first beam expander 10 and second beam expander 20 outside optical resonator
   5.1 Configuration
   5.2 Effect
6. Others
   6.1 Electronic Device Manufacturing Method
   6.2 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

### 1.1 Configuration of Gas Laser Device 100

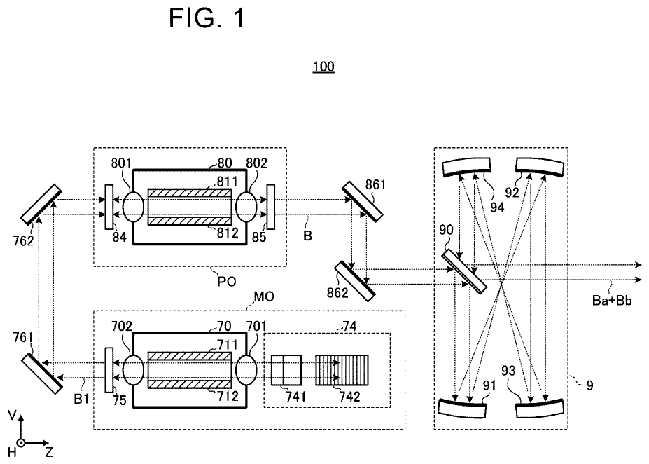

FIG. 1 shows the configuration of a gas laser device 100 according to a comparative example. The comparative example of the present disclosure is an example recognized by the applicant as known only by the applicant, and is not a publicly known example admitted by the applicant. The gas laser device 100 includes a laser oscillator MO, a laser amplifier PO, and an optical pulse stretcher 9.

The laser oscillator MO includes a laser chamber 70, a line narrowing module 74, and an output coupling mirror 75.

The laser chamber 70 is arranged on the optical path of an optical resonator configured by the line narrowing module 74 and the output coupling mirror 75. The laser chamber 70 is provided with two windows 701, 702. The windows 701, 702 are arranged in a manner similar to the windows 801, 802 shown in FIG. 2 such that the incident angle of light passing through the optical path of the optical resonator is approximately the Brewster angle.

The laser chamber 70 accommodates discharge electrodes 711, 712. The discharge electrodes 711, 712 are connected to a pulse power source (not shown). The laser chamber 70 contains a laser gas as a laser medium. The laser gas includes, for example, an argon gas, a fluorine gas, and a neon gas. Alternatively, the laser gas includes, for example, a krypton gas, a fluorine gas, and a neon gas.

The line narrowing module 74 includes wavelength selection elements such as a prism 741 and a grating 742. The output coupling mirror 75 is configured by a partial reflection mirror.

High reflection mirrors 761, 762 are arranged in this order on the optical path of pulse laser light B1 output from the output coupling mirror 75.

The laser amplifier PO includes a laser chamber 80, a rear mirror 84, and an output coupling mirror 85. The laser chamber 80, the output coupling mirror 85, and the windows 801, 802 and discharge electrodes 811, 812 associated with the laser chamber 80 are similar to the corresponding components in the laser oscillator MO.

The rear mirror 84 is arranged on the optical path of the pulse laser light B1 reflected by the high reflection mirror 762. The rear mirror 84 is configured by a partial reflection mirror having a higher reflectance than the output coupling mirror 85. The rear mirror 84 and the output coupling mirror 85 configure an optical resonator.

The travel direction of pulse laser light B output from the laser amplifier PO is represented by a Z direction. A direction in which the discharge electrodes 811, 812 face each other is represented by a V direction or a −V direction. The Z direction and the V direction are perpendicular to each other, and the direction perpendicular to both of them is represented by an H direction or a −H direction. In FIG. 1, the configuration of the gas laser device 100 is shown as viewed in the −H direction. The V direction corresponds to the first direction in the present disclosure, and the H direction corresponds to the second direction in the present disclosure. The Z direction corresponds to the output direction in the present disclosure.

High reflection mirrors 861, 862 are arranged in this order on the optical path of the pulse laser light B output from the output coupling mirror 85.

The optical pulse stretcher 9 is arranged on the optical path of the pulse laser light B output from the high reflection mirror 862. The optical pulse stretcher 9 includes a beam splitter 90 and first to fourth concave mirrors 91 to 94.

### 1.2 Operation of Gas Laser Device 100

In the laser oscillator MO, the pulse power source (not shown) generates a pulse high voltage and applies the high voltage between the discharge electrodes 711, 712. When the high voltage is applied between the discharge electrodes 711, 712, discharge occurs between the discharge electrodes 711, 712. The laser gas in the laser chamber 70 is excited by the energy of the discharge and shifts to a high energy level. When the excited laser gas then shifts to a low energy level, light having a wavelength corresponding to the difference between the energy levels is emitted.

The light generated in the laser chamber 70 is output to the outside of the laser chamber 70 through the windows 701, 702. The beam width of the light output from the window 710 is expanded by the prism 741, and then the light is incident on the grating 742. The light incident on the grating 742 from the prism 741 is reflected by a plurality of grooves formed on the grating 742 and is diffracted in a direction corresponding to the wavelength of the light. The grating 742 is arranged in the Littrow arrangement, which causes the incident angle of the light incident on the grating 742 from the prism 741 to coincide with the diffraction angle of the diffracted light having a desired wavelength. Thus, light having a wavelength close to the desired wavelength including the ultraviolet wavelength returns into the laser chamber 70 via the prism 741.

The output coupling mirror 75 transmits and outputs a part of the light output from the window 702, and reflects the other part back into the laser chamber 70.

In this way, the light output from the laser chamber 70 reciprocates between the line narrowing module 74 and the output coupling mirror 75. This light is amplified each time when passing through a discharge space between the discharge electrodes 711, 712, and the polarization component in the H direction is selected each time when the light passes through the windows 701, 702. Further, the light is line-narrowed each time being turned back in the line narrowing module 74. Thus, the light having undergone laser oscillation and line narrowing is output as the pulse laser light B1 from the output coupling mirror 75. Since the discharge space between the discharge electrodes 711, 712 is longer in the V direction than in the H direction, the pulse laser light B1 has a beam cross section longer in the V direction than in the H direction.

The pulse laser light B1 output from the output coupling mirror 75 enters the laser chamber 80 of the laser amplifier PO via the high reflection mirror 761, the high reflection mirror 762, and the rear mirror 84.

In the laser amplifier PO, in synchronization with the entrance of the pulse laser light B1 into the laser chamber 80, a pulse power source (not shown) generates a pulse high voltage and applies the high voltage between the discharge electrodes 811, 812.

When the high voltage is applied between the discharge electrodes 811, 812, discharge occurs between the discharge electrodes 811, 812. The pulse laser light B1 having entered the laser chamber 80 is amplified by the energy of the discharge.

The light amplified in the laser chamber 80 reciprocates between the rear mirror 84 and the output coupling mirror 85. This light is amplified each time when passing through a discharge space between the discharge electrodes 811, 812, and the polarization component in the H direction is selected each time when the light passes through the windows 801, 802. The amplified pulse laser light B is output from the output coupling mirror 85. The pulse laser light B has a wavelength spectrum equivalent to that of the pulse laser light B1 output from the laser oscillator MO. The pulse laser light B has a beam cross section longer in the V direction than in the H direction.

The pulse laser light B output from the output coupling mirror 85 is incident on the beam splitter 90 of the optical pulse stretcher 9 in the Z direction via the high reflection mirror 861 and the high reflection mirror 862.

The beam splitter 90 transmits a part of the pulse laser light B incident thereon in the Z direction, outputs the part thereof as a beam Ba, and reflects the other part thereof in the −V direction. The reflected pulse laser light B is sequentially reflected by the first to fourth concave mirrors 91 to 94, and is incident on the beam splitter 90 in the −V direction.

The beam cross section of the pulse laser light B incident from the high reflection mirror 862 on the beam splitter 90 is imaged on the beam splitter 90 with a size of 1:1 owing to the first to fourth concave mirrors 91 to 94. The beam splitter 90 reflects, in the Z direction, a part of the pulse laser light B incident thereon in the −V direction from the fourth concave mirror 94 and outputs the part thereof as a beam Bb.

There is a time difference between the beam Ba and the beam Bb according to the optical path length of the delay optical path formed by the first to fourth concave mirrors 91 to 94. By spatially overlapping the beam Ba and the beam Bb, it is possible to output pulse laser light Ba+Bb having an extended pulse width.

### 2. Problem of Comparative Example

Since the pulse laser light B output from the laser amplifier PO has a large pulse energy, there is a problem that the output coupling mirror 85 and the optical pulse stretcher 9 are likely to deteriorate and have a short lifetime.

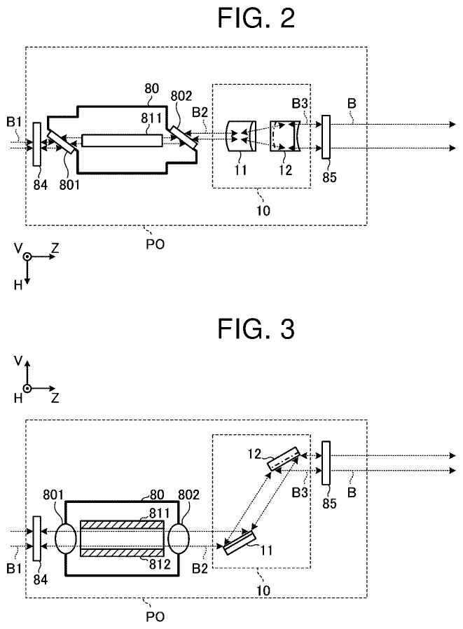

FIG. 2 and FIG. 3 show the configuration of the laser amplifier PO according to an improved configuration of the comparative example. In FIG. 2, the configuration of the laser amplifier PO viewed in the −V direction is shown, and in FIG. 3, the configuration of the laser amplifier PO viewed in the −H direction is shown. In the improved configuration, a first beam expander 10 is arranged between the laser chamber 80 and the output coupling mirror 85. The pulse laser light output from the window 802 of the laser chamber 80 in the Z direction is referred to as B2, and the pulse laser light output from the first beam expander 10 in the Z direction is referred to as B3. In the improved configuration, light having passed through the output coupling mirror 85 among the pulse laser light B3 corresponds to the pulse laser light B.

The first beam expander 10 includes a first convex cylindrical mirror 11 and a first concave cylindrical mirror 12. The first convex cylindrical mirror 11 and the first concave cylindrical mirror 12 are arranged such that the pulse laser light B2 output from the window 802 of the laser chamber 80 in the Z direction is reflected by the first convex cylindrical mirror 11 and the first concave cylindrical mirror 12 in this order, and is incident on the output coupling mirror 85 as the pulse laser light B3. The focal lines of the first convex cylindrical mirror 11 and the first concave cylindrical mirror 12 substantially coincide with each other. Here, the focal line of the cylindrical mirror is an imaginary line formed by connecting focal points of the cylindrical mirror. The pulse laser light B2 is configured to be incident on each of the first convex cylindrical mirror 11 and the first concave cylindrical mirror 12 as S-polarized light, and the incident angle thereof is 45 degrees or more.

The pulse laser light B2 reflected by the first convex cylindrical mirror 11 is incident on the first concave cylindrical mirror 12 while spreading with the focal line of the first convex cylindrical mirror 11 as a center. Upon being reflected by the first concave cylindrical mirror 12, the pulse laser light B2 is output from the first concave cylindrical mirror 12 as the collimated pulse laser light B3. As a result, the pulse laser light B2 is incident on the output coupling mirror 85 as the pulse laser light B3 having a beam width expanded in the H direction and reduced energy density, so that deterioration of the output coupling mirror 85 and the optical pulse stretcher 9 can be suppressed.

The larger the magnification ratio of the beam width by the first beam expander 10, the higher the effect of suppressing deterioration of the output coupling mirror 85 and the optical pulse stretcher 9. In order to increase the magnification ratio of the beam width, it is necessary to reduce the radius of curvature of each of the first convex cylindrical mirror 11 and the first concave cylindrical mirror 12. However, when the radius of curvature is reduced, spherical aberration increases, and a larger part of the pulse laser light B3 deviates from the optical path of the optical resonator or the optical pulse stretcher 9, so that the pulse energy of the pulse laser light B decreases.

Embodiments described below relate to suppressing decrease of the pulse energy of the pulse laser light B while suppressing deterioration of the output coupling mirror 85 and the optical pulse stretcher 9.

### 3. Laser Amplifier PO Including Second Beam Expander 20

### 3.1 Configuration

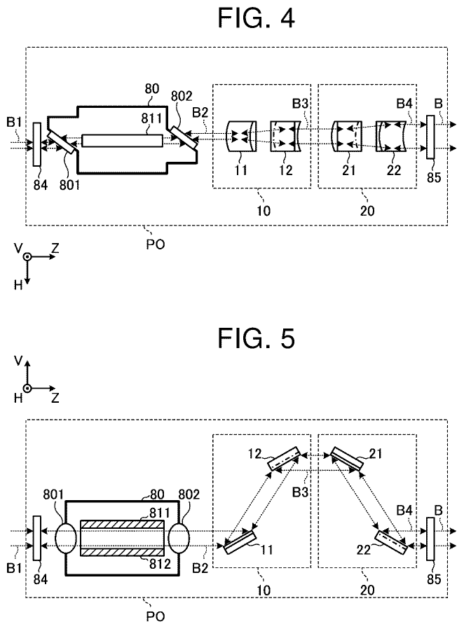

FIG. 4 and FIG. 5 show the configuration of the laser amplifier PO according to a first embodiment. In the first embodiment, a second beam expander 20 is arranged between the first beam expander 10 and the output coupling mirror 85, that is, on the optical path of the pulse laser light B3 output from the first beam expander 10 in the Z direction. The pulse laser light output from the second beam expander 20 in the Z direction is referred to as pulse laser light B4. In the first embodiment, light having passed through the output coupling mirror 85 among the pulse laser light B4 corresponds to the pulse laser light B. The optical pulse stretcher 9 (see FIG. 1) is arranged on the optical path of the pulse laser light B.

The second beam expander 20 includes a second convex cylindrical mirror 21 and a second concave cylindrical mirror 22. The second convex cylindrical mirror 21 and the second concave cylindrical mirror 22 are arranged such that the pulse laser light B3 output from the first concave cylindrical mirror 12 is reflected by the second convex cylindrical mirror 21 and the second concave cylindrical mirror 22 in this order, and is incident on the output coupling mirror 85. The focal lines of the second convex cylindrical mirror 21 and the second concave cylindrical mirror 22 substantially coincide with each other. The incident angle of the pulse laser light B3 with respect to each of the second convex cylindrical mirror 21 and the second concave cylindrical mirror 22 is 45 degrees or more.

The beam width of the pulse laser light B3 is further expanded in the H direction by the second beam expander 20, and the pulse laser light B3 is incident on the output coupling mirror 85 as the pulse laser light B4 having reduced energy density.

### 3.2 Magnification Ratio of Beam Width

The magnification ratio of the beam width in the H direction by the second beam expander 20 is preferably equal to or more than 85% and equal to or less than 115% of the magnification ratio of the beam width in the H direction by the first beam expander 10. These magnification ratios may be equal to each other. The magnification ratio of the beam width in the H direction by each of the first beam expander 10 and the second beam expander 20 is preferably more than 1 and equal to or less than 2. Here, the beam width is defined as the full width at half maximum of the intensity distribution of the beam cross section of the pulse laser light.

When the radius of curvature of the first convex cylindrical mirror 11 is R1 and the radius of curvature of the first concave cylindrical mirror 12 is R2, the magnification ratio of the first beam expander 10 is given by R2/R1. When the radius of curvature of the second convex cylindrical mirror 21 is R3 and the radius of curvature of the second concave cylindrical mirror 22 is R4, the magnification ratio of the second beam expander 20 is given by R4/R3. The combined magnification ratio of the first beam expander 10 and the second beam expander 20 is given by (R2/R1)×(R4/R3). Each of the radius of curvature R1 of the first convex cylindrical mirror 11 and the radius of curvature R3 of the second convex cylindrical mirror 21 is preferably equal to or more than 20 mm and equal to or less than 80 mm. The radius of curvature R2 of the first concave cylindrical mirror 12 is determined by the radius of curvature R1 and the magnification ratio of the first beam expander 10. The radius of curvature R4 of the second concave cylindrical mirror 22 is determined by the radius of curvature R3 and the magnification ratio of the second beam expander 20.

The magnification ratios of the beam width in the V direction by the first beam expander 10 and the second beam expander 20 are each smaller than their magnification ratios of the beam width in the H direction, and may be 1, for example.

### 3.3 Shift of Optical Axis

As shown in FIG. 5, the optical axis of the pulse laser light B3 output from the first beam expander 10 is shifted in the V direction with respect to the optical axis of the pulse laser light B2 incident on the first beam expander 10. On the other hand, the optical axis of the pulse laser light B4 output from the second beam expander 20 is shifted in the −V direction with respect to the optical axis of the pulse laser light B3 incident on the second beam expander 20. Thus, the first beam expander 10 and the second beam expander 20 shift the optical axes in opposite directions. The shift of the optical axis of the pulse laser light B4 output from the second concave cylindrical mirror 22 with respect to the optical axis of the pulse laser light B2 incident on the first convex cylindrical mirror 11 is smaller than any of the shift of the optical axis by the first beam expander 10 and the shift of the optical axis by the second beam expander 20.

### 3.4 Inclination of Optical Axis

It is desirable that the inclination of the optical axis of the pulse laser light B4 output from the second concave cylindrical mirror 22 with respect to the optical axis of the pulse laser light B2 incident on the first convex cylindrical mirror 11 is 0, that is, these optical axes are coaxial or parallel. Even when the inclination between the optical axes is not 0, it is desirable that the inclination between the optical axes is smaller than any of inclinations below:
(a) the inclination of the optical axis of the pulse laser light B2 output from the first convex cylindrical mirror 11 with respect to the optical axis of the pulse laser light B2 incident on the first convex cylindrical mirror 11;
(b) the inclination of the optical axis of the pulse laser light B3 output from the first concave cylindrical mirror 12 with respect to the optical axis of the pulse laser light B2 incident on the first concave cylindrical mirror 12;
(c) the inclination of the optical axis of the pulse laser light B3 output from the second convex cylindrical mirror 21 with respect to the optical axis of the pulse laser light B3 incident on the second convex cylindrical mirror 21; and
(d) the inclination of the optical axis of the pulse laser light B4 output from the second concave cylindrical mirror 22 with respect to the optical axis of the pulse laser light B3 incident on the second concave cylindrical mirror 22.

### 3.5 Beam Divergence Angle

The pulse laser light B2 output from the first convex cylindrical mirror 11 is incident on the first concave cylindrical mirror 12 while spreading in the H direction, and the pulse laser light B3 output from the second convex cylindrical mirror 21 is incident on the second concave cylindrical mirror 22 while spreading in the H direction. The beam divergence angle of the pulse laser light B4 incident on the output coupling mirror 85 is preferably smaller than any of the beam divergence angle of the pulse laser light B2 incident on the first concave cylindrical mirror 12 and the beam divergence angle of the pulse laser light B3 incident on the second concave cylindrical mirror 22. Further, each of the beam divergence angle of the pulse laser light B2 incident on the first convex cylindrical mirror 11, the beam divergence angle of the pulse laser light B3 incident on the second convex cylindrical mirror 21, and the beam divergence angle of the pulse laser light B4 output from the second concave cylindrical mirror 22 is preferably smaller than any of the beam divergence angle of the pulse laser light B2 incident on the first concave cylindrical mirror 12 and the beam divergence angle of the pulse laser light B3 incident on the second concave cylindrical mirror 22.

### 3.6 Effect

(1) According to the first embodiment, the gas laser device 100 includes the laser oscillator MO, the laser amplifier PO, the first beam expander 10, the second beam expander 20, and the optical pulse stretcher 9. The laser oscillator MO outputs the pulse laser light B1 having an ultraviolet wavelength. The laser amplifier PO amplifies the pulse laser light B1 output from the laser oscillator MO. The laser amplifier PO includes the optical resonator including the output coupling mirror 85 that outputs the amplified pulse laser light B, and the laser chamber 80 arranged on the optical path of the optical resonator and including the pair of discharge electrodes 811, 812. The first beam expander 10 is arranged downstream of the laser chamber 80 in the Z direction, which is the output direction of the pulse laser light B, and expands the beam width of the pulse laser light B2 output from the laser chamber 80. The second beam expander 20 further expands the beam width of the pulse laser light B3 output from the first beam expander 10. The optical pulse stretcher 9 expands the pulse width of the pulse laser light B4 output from the second beam expander 20.

Accordingly, by expanding the beam width by a plurality of beam expanders, it is possible to suppress deterioration of optical elements of the subsequent stage by sufficiently expanding the beam width even with the magnification ratio of each beam expander being small. By reducing the magnification ratio of each beam expander, spherical aberration can be suppressed, and decrease in the pulse energy of the pulse laser light B can be suppressed. Further, by reducing the magnification ratio of each beam expander, the allowable range of positional deviation of the optical elements configuring the beam expander increases, and the robustness can be improved.

In addition to the first and second beam expanders 10, 20, a third beam expander may also be provided, in which case the magnification ratio of each beam expander may be further reduced. However, it is desirable not to make the resonator length of the optical resonator too long.

(2) According to the first embodiment, the magnification ratio of the second beam expander 20 is equal to or more than 85% and equal to or less than 115% of the magnification ratio of the first beam expander 10.

Accordingly, by reducing the difference between the magnification ratios of the first and second beam expanders 10, 20, it is possible to sufficiently expand the beam width even with the magnification ratio of each beam expander being small, and to suppress deterioration of the optical elements of the subsequent stage.

(3) According to the first embodiment, the magnification ratio of the second beam expander 20 is equal to the magnification ratio of the first beam expander 10.

Accordingly, by making the magnification ratios of the first and second beam expanders 10, 20 equal to each other, it is possible to sufficiently expand the beam width even with the magnification ratio of each beam expander being small.

(4) According to the first embodiment, the magnification ratio of the first beam expander 10 and the magnification ratio of the second beam expander 20 are each more than 1 and equal to or less than 2.

Accordingly, by setting the magnification ratio of each of the first and second beam expanders 10, 20 to 2 or less, it is possible to suppress spherical aberration and suppress decrease in the pulse energy of the pulse laser light B.

(5) According to the first embodiment, each of the first beam expander 10 and the second beam expander 20 expands the beam width at a larger magnification ratio in the H direction, which is perpendicular to both the V direction and the optical axis direction of the pulse laser light B2, B3 than in the V direction in which the discharge electrodes 811, 812 face each other.

Accordingly, since the beam width is expanded in the H direction, it is possible to suppress deviation of the aspect ratio in the beam cross-sectional shape of the pulse laser light B.

(6) According to the first embodiment, the first beam expander 10 shifts, in the V direction perpendicular to the Z direction, the optical axis of the pulse laser light B3 output from the first beam expander 10 with respect to the optical axis of the pulse laser light B2 incident on the first beam expander 10. The second beam expander 20 shifts, in the −V direction opposite to the V direction, the optical axis of the pulse laser light B4 output from the second beam expander 20 with respect to the optical axis of the pulse laser light B3 incident on the second beam expander 20.

Accordingly, since the first and second beam expanders 10, 20 shift the optical axis in opposite directions, the shift of the optical axis due to passage through the first and second beam expanders 10, 20 can be reduced.

(7) According to the first embodiment, the first beam expander 10 includes the first convex cylindrical mirror 11 on which the pulse laser light B2 output from the laser chamber 80 is incident, and the first concave cylindrical mirror 12 on which the pulse laser light B2 reflected by the first convex cylindrical mirror 11 is incident. The second beam expander 20 includes the second convex cylindrical mirror 21 on which the pulse laser light B3 output from the first concave cylindrical mirror 12 is incident, and the second concave cylindrical mirror 22 on which the pulse laser light B3 reflected by the second convex cylindrical mirror 21 is incident.

Accordingly, energy loss can be reduced by using the reflection optical element. Since the reflection optical element is a cylindrical mirror, the direction in which the beam width is expanded can be defined. By providing a plurality of beam expanders configured by a combination of a convex cylindrical mirror and a concave cylindrical mirror, spherical aberration can be suppressed.

(8) According to the first embodiment, the first beam expander 10 shifts, in the V direction in which the discharge electrodes 811, 812 face each other, the optical axis of the pulse laser light B3 output from the first beam expander 10 with respect to the optical axis of the pulse laser light B2 incident on the first beam expander 10. The second beam expander 20 shifts, in the −V direction opposite to the V direction, the optical axis of the pulse laser light B4 output from the second beam expander 20 with respect to the optical axis of the pulse laser light B3 incident on the second beam expander 20.

Accordingly, since the optical axis is shifted in the V direction and the −V direction by the combination of the convex cylindrical mirror and the concave cylindrical mirror, light incident on the cylindrical mirror becomes S-polarized light, and energy loss can be reduced.

(9) According to the first embodiment, the shift of the optical axis of the pulse laser light B4 output from the second concave cylindrical mirror 22 with respect to the optical axis of the pulse laser light B2 incident on the first convex cylindrical mirror 11 is smaller than any of the shift of the optical axis of the pulse laser light B3 output from the first concave cylindrical mirror 12 with respect to the optical axis of the pulse laser light B2 incident on the first convex cylindrical mirror 11 and the shift of the optical axis of the pulse laser light B4 output from the second concave cylindrical mirror 22 with respect to the optical axis of the pulse laser light B3 incident on the second convex cylindrical mirror 21.

Accordingly, by combining the first and second beam expanders 10, 20 to reduce the shift of the optical axis, adding the first and second beam expanders 10, 20 to the existing gas laser device 100 can be facilitated.

(10) According to the first embodiment, the inclination of the optical axis of the pulse laser light B4 output from the second concave cylindrical mirror 22 with respect to the optical axis of the pulse laser light B2 incident on the first convex cylindrical mirror 11 is smaller than any of the inclinations below:
(a) the inclination of the optical axis of the pulse laser light B2 output from the first convex cylindrical mirror 11 with respect to the optical axis of the pulse laser light B2 incident on the first convex cylindrical mirror 11;
(b) the inclination of the optical axis of the pulse laser light B3 output from the first concave cylindrical mirror 12 with respect to the optical axis of the pulse laser light B2 incident on the first concave cylindrical mirror 12;
(c) the inclination of the optical axis of the pulse laser light B3 output from the second convex cylindrical mirror 21 with respect to the optical axis of the pulse laser light B3 incident on the second convex cylindrical mirror 21; and
(d) the inclination of the optical axis of the pulse laser light B4 output from the second concave cylindrical mirror 22 with respect to the optical axis of the pulse laser light B3 incident on the second concave cylindrical mirror 22.

Accordingly, by suppressing the inclination of the optical axis due to the first and second beam expanders 10, 20, the gas laser device 100 can be easily designed.
(11) According to the first embodiment, the beam divergence angle of the pulse laser light B4 incident on the output coupling mirror 85 is smaller than any of the beam divergence angle of the pulse laser light B2 incident on the first concave cylindrical mirror 12 and the beam divergence angle of the pulse laser light B3 incident on the second concave cylindrical mirror 22.

Accordingly, even if the output coupling mirror 85 is a planar mirror, a large portion of the light reflected by the output coupling mirror 85 can be returned into the laser chamber 80, and energy loss can be reduced.
(12) According to the first embodiment, each of the beam divergence angle of the pulse laser light B2 incident on the first convex cylindrical mirror 11, the beam divergence angle of the pulse laser light B3 incident on the second convex cylindrical mirror 21, and the beam divergence angle of the pulse laser light B4 output from the second concave cylindrical mirror 22 is smaller than any of the beam divergence angle of the pulse laser light B2 incident on the first concave cylindrical mirror 12 and the beam divergence angle of the pulse laser light B3 incident on the second concave cylindrical mirror 22.

Accordingly, the optical system can be easily designed by collimating the beams incident on and output from the first and second beam expanders 10, 20.

(13) According to the first embodiment, the first beam expander 10 and the second beam expander 20 are arranged between the laser chamber 80 and the output coupling mirror 85.

Accordingly, by making the beam expanded by the first and second beam expanders 10, 20 to be incident on the output coupling mirror 85, the lifetime of both the output coupling mirror 85 and the optical pulse stretcher 9 can be increased.

(14) According to the first embodiment, the radius of curvature R1 of the first convex cylindrical mirror 11 and the radius of curvature R3 of the second convex cylindrical mirror 21 are each equal to or more than 20 mm and equal to or less than 80 mm.

Accordingly, spherical aberration can be suppressed by setting the radii of curvature R1, R3 of the first and second convex cylindrical mirrors 11, 21 to be equal to or more than 20 mm. Further, by setting the radii of curvature R1, R3 to be equal to or less than 80 mm, the resonator length can be suppressed, and thus energy loss in the optical resonator can be reduced.

In other respects, the first embodiment is similar to the comparative example.

### 4. Example of Arranging Second Beam Expander 20 Outside Optical Resonator

### 4.1 Configuration

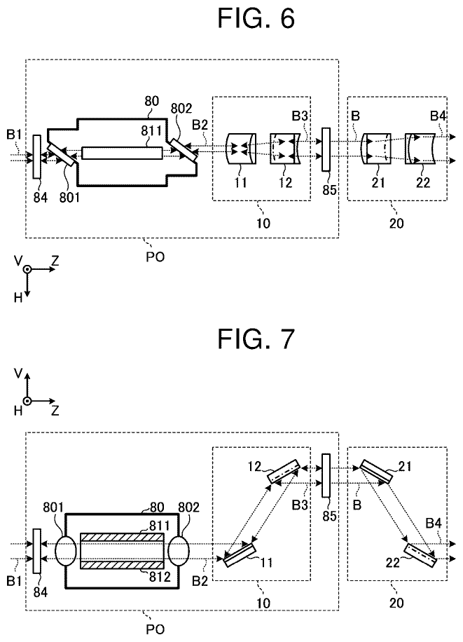

FIG. 6 and FIG. 7 show the configurations of the laser amplifier PO and the second beam expander 20 according to a second embodiment. In the second embodiment, the second beam expander 20 is arranged on the optical path of the pulse laser light B between the output coupling mirror 85 and the optical pulse stretcher 9 (see FIG. 1). That is, the output coupling mirror 85 is arranged on the optical path of the pulse laser light B3 between the first beam expander 10 and the second beam expander 20. In the second embodiment, light having passed through the output coupling mirror 85 among the pulse laser light B3 corresponds to the pulse laser light B.

The radius of curvature R1 of the first convex cylindrical mirror 11 is preferably equal to or more than 20 mm and equal to or less than 80 mm, and the radius of curvature R3 of the second convex cylindrical mirror 21 is preferably equal to or more than 20 mm and equal to or less than 100 mm. The radius of curvature R3 may be larger than the radius of curvature R1.

### 4.2 Effect

(15) According to the second embodiment, the first beam expander 10 is arranged between the laser chamber 80 and the output coupling mirror 85, and the second beam expander 20 is arranged between the output coupling mirror 85 and the optical pulse stretcher 9.

Accordingly, by arranging the output coupling mirror 85 between the first and second beam expanders 10, 20, the lifetime of the output coupling mirror 85 and the optical pulse stretcher 9 can be increased. Further, since the resonator length can be set shorter than that in the first embodiment, energy loss in the optical resonator can be reduced, and decrease in the pulse energy of the pulse laser light B can be suppressed.

(16) According to the second embodiment, the radius of curvature R1 of the first convex cylindrical mirror 11 is equal to or more than 20 mm and equal to or less than 80 mm, and the radius of curvature R3 of the second convex cylindrical mirror 21 is equal to or more than 20 mm and equal to or less than 100 mm.

Accordingly, spherical aberration can be suppressed by setting the radii of curvature R1, R3 of the first and second convex cylindrical mirrors 11, 21 to be equal to or more than 20 mm. Further, by setting the radius of curvature R1 of the first convex cylindrical mirror 11 arranged on the optical resonator to be equal to or less than 80 mm, the resonator length can be suppressed, and thus energy loss in the optical resonator can be reduced. Further, by setting the radius of curvature R3 of the second convex cylindrical mirror 21 arranged outside the optical resonator to be equal to or less than 100 mm, the size of the gas laser device 100 can be suppressed.

(17) According to the second embodiment, the radius of curvature R3 of the second convex cylindrical mirror 21 is larger than the radius of curvature R1 of the first convex cylindrical mirror 11.

Accordingly, by reducing the radius of curvature R1, the first beam expander 10 can be made compact and the resonator length can be suppressed. Further, the radius of curvature R3 can be increased without affecting the resonator length, and the flexibility of designing the second beam expander 20 can be improved.

In other respects, the second embodiment is similar to the first embodiment.

### 5. Example of Arranging First Beam Expander 10 and Second Beam Expander 20 Outside Optical Resonator

### 5.1 Configuration

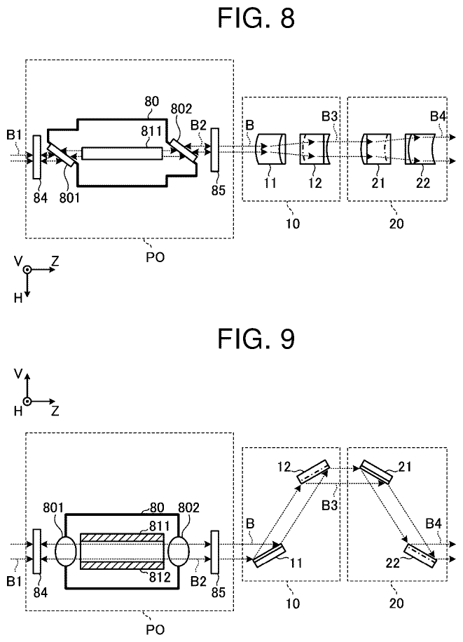

FIG. 8 and FIG. 9 show the configurations of the laser amplifier PO, the first beam expander 10, and the second beam expander 20 according to a third embodiment. In the third embodiment, the first beam expander 10 and the second beam expander 20 are arranged on the optical path of the pulse laser light B between the output coupling mirror 85 and the optical pulse stretcher 9 (see FIG. 1). That is, the output coupling mirror 85 is arranged on the optical path of the pulse laser light B2 between the laser chamber 80 and the first beam expander 10. In the third embodiment, light having passed through the output coupling mirror 85 among the pulse laser light B2 corresponds to the pulse laser light B.

Each of the radius of curvature R1 of the first convex cylindrical mirror 11 and the radius of curvature R3 of the second convex cylindrical mirror 21 is preferably equal to or more than 20 mm and equal to or less than 100 mm.

### 5.2 Effect

(18) According to the third embodiment, the first beam expander 10 and the second beam expander 20 are arranged between the output coupling mirror 85 and the optical pulse stretcher 9.

Accordingly, by arranging the first and second beam expanders 10, 20 between the optical resonator and the optical pulse stretcher 9, the lifetime of the optical pulse stretcher 9 can be increased. Further, since the resonator length can be set even shorter than that in the second embodiment, energy loss in the optical resonator can be reduced, and decrease in the pulse energy of the pulse laser light B can be further suppressed.

(19) According to the third embodiment, the radius of curvature R1 of the first convex cylindrical mirror 11 and the radius of curvature R3 of the second convex cylindrical mirror 21 are each equal to or more than 20 mm and equal to or less than 100 mm.

Accordingly, since the first and second beam expanders 10, 20 are arranged outside the optical resonator, the radii of curvature R1, R3 can be increased without affecting the resonator length, and the flexibility of designing can be ensured. Further, spherical aberration can be suppressed by setting the radii of curvature R1, R3 to be equal to or more than 20 mm. Further, by setting the radii of curvature R1, R3 to be equal to or less than 100 mm, the size of the gas laser device 100 can be suppressed.

In other respects, the third embodiment is similar to the first embodiment.

### 6. Others

### 6.1 Electronic Device Manufacturing Method

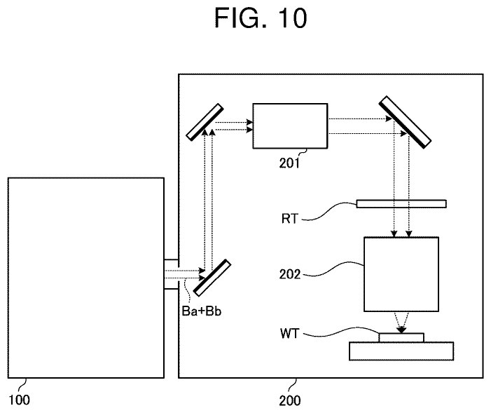

FIG. 10 shows the configuration of an exposure system. The exposure system includes the gas laser device 100 and an exposure apparatus 200. The gas laser device 100 is configured to output the pulse laser light Ba+Bb toward the exposure apparatus 200.

The exposure apparatus 200 includes an illumination optical system 201 and a projection optical system 202. The illumination optical system 201 illuminates a reticle pattern of a reticle (not shown) arranged on a reticle stage RT with the pulse laser light Ba+Bb having entered from the gas laser device 100. The projection optical system 202 causes the pulse laser light Ba+Bb transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 200 synchronously translates the reticle stage RT and the workpiece table WT to expose the workpiece to the pulse laser light Ba+Bb reflecting the reticle pattern. After the reticle pattern is transferred onto the semiconductor wafer by the exposure process described above, an electronic device can be manufactured through a plurality of processes.

### 6.2 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A gas laser device comprising:
a laser oscillator configured to output pulse laser light having an ultraviolet wavelength;
a laser amplifier configured to amplify the pulse laser light output from the laser oscillator, and including an optical resonator including an output coupling mirror configured to output the amplified pulse laser light, and a laser chamber arranged on an optical path of the optical resonator and including a pair of discharge electrodes;
a first beam expander arranged downstream of the laser chamber in an output direction of the pulse laser light and configured to expand a beam width of the pulse laser light output from the laser chamber;
a second beam expander configured to further expand the beam width of the pulse laser light output from the first beam expander; and
an optical pulse stretcher configured to extend a pulse width of the pulse laser light output from the second beam expander.

2. The gas laser device according to claim 1,
wherein a magnification ratio of the second beam expander is equal to or more than 85% and equal to or less than 115% of a magnification ratio of the first beam expander.

3. The gas laser device according to claim 1,
wherein a magnification ratio of the second beam expander is equal to a magnification ratio of the first beam expander.

4. The gas laser device according to claim 1,
wherein a magnification ratio of the first beam expander and a magnification ratio of the second beam expander are each more than 1 and equal to or less than 2.

5. The gas laser device according to claim 1,
wherein each of the first beam expander and the second beam expander expands the beam width at a larger magnification ratio in a second direction than in a first direction in which the discharge electrodes face each other, the second direction being perpendicular to both the first direction and an optical axis direction of the pulse laser light.

6. The gas laser device according to claim 1,
wherein the first beam expander shifts, in a first direction perpendicular to the output direction, an optical axis of the pulse laser light output from the first beam expander with respect to an optical axis of the pulse laser light incident on the first beam expander, and
the second beam expander shifts, in a direction opposite to the first direction, an optical axis of the pulse laser light output from the second beam expander with respect to an optical axis of the pulse laser light incident on the second beam expander.

7. The gas laser device according to claim 1,
wherein the first beam expander includes a first convex cylindrical mirror on which the pulse laser light output from the laser chamber is incident, and a first concave cylindrical mirror on which the pulse laser light reflected by the first convex cylindrical mirror is incident, and
the second beam expander includes a second convex cylindrical mirror on which the pulse laser light output from the first concave cylindrical mirror is incident, and a second concave cylindrical mirror on which the pulse laser light reflected by the second convex cylindrical mirror is incident.

8. The gas laser device according to claim 7,
wherein the first beam expander shifts, in a first direction in which the discharge electrodes face each other, an optical axis of the pulse laser light output from the first beam expander with respect to an optical axis of the pulse laser light incident on the first beam expander, and
the second beam expander shifts, in a direction opposite to the first direction, an optical axis of the pulse laser light output from the second beam expander with respect to an optical axis of the pulse laser light incident on the second beam expander.

9. The gas laser device according to claim 7,
wherein a shift of an optical axis of the pulse laser light output from the second concave cylindrical mirror with respect to an optical axis of the pulse laser light incident on the first convex cylindrical mirror is smaller than any of a shift of an optical axis of the pulse laser light output from the first concave cylindrical mirror with respect to the optical axis of the pulse laser light incident on the first convex cylindrical mirror and a shift of the optical axis of the pulse laser light output from the second concave cylindrical mirror with respect to an optical axis of the pulse laser light incident on the second convex cylindrical mirror.

10. The gas laser device according to claim 7,
wherein an inclination of an optical axis of the pulse laser light output from the second concave cylindrical mirror with respect to an optical axis of the pulse laser light incident on the first convex cylindrical mirror is smaller than any of an inclination of an optical axis of the pulse laser light output from the first convex cylindrical mirror with respect to the optical axis of the pulse laser light incident on the first convex cylindrical mirror, an inclination of an optical axis of the pulse laser light output from the first concave cylindrical mirror with respect to an optical axis of the pulse laser light incident on the first concave cylindrical mirror, an inclination of an optical axis of the pulse laser light output from the second convex cylindrical mirror with respect to an optical axis of the pulse laser light incident on the second convex cylindrical mirror, and an inclination of the optical axis of the pulse laser light output from the second concave cylindrical mirror with respect to an optical axis of the pulse laser light incident on the second concave cylindrical mirror.

11. The gas laser device according to claim 7,
wherein a beam divergence angle of the pulse laser light incident on the output coupling mirror is smaller than any of a beam divergence angle of the pulse laser light incident on the first concave cylindrical mirror and a beam divergence angle of the pulse laser light incident on the second concave cylindrical mirror.

12. The gas laser device according to claim 7,
wherein each of a beam divergence angle of the pulse laser light incident on the first convex cylindrical mirror, a beam divergence angle of the pulse laser light incident on the second convex cylindrical mirror, and a beam divergence angle of the pulse laser light output from the second concave cylindrical mirror is smaller than any of a beam divergence angle of the pulse laser light incident on the first concave cylindrical mirror and a beam divergence angle of the pulse laser light incident on the second concave cylindrical mirror.

13. The gas laser device according to claim 7,
wherein the first beam expander and the second beam expander are arranged between the laser chamber and the output coupling mirror.

14. The gas laser device according to claim 13,
wherein a radius of curvature of the first convex cylindrical mirror and a radius of curvature of the second convex cylindrical mirror are each equal to or more than 20 mm and equal to or less than 80 mm.

15. The gas laser device according to claim 7,
wherein the first beam expander is arranged between the laser chamber and the output coupling mirror, and the second beam expander is arranged between the output coupling mirror and the optical pulse stretcher.

16. The gas laser device according to claim 15,
wherein a radius of curvature of the first convex cylindrical mirror is equal to or more than 20 mm and equal to or less than 80 mm, and
a radius of curvature of the second convex cylindrical mirror is equal to or more than 20 mm and equal to or less than 100 mm.

17. The gas laser device according to claim 15,
wherein a radius of curvature of the second convex cylindrical mirror is larger than a radius of curvature of the first convex cylindrical mirror.

18. The gas laser device according to claim 7,
wherein the first beam expander and the second beam expander are arranged between the output coupling mirror and the optical pulse stretcher.

19. The gas laser device according to claim 18,
wherein a radius of curvature of the first convex cylindrical mirror and a radius of curvature of the second convex cylindrical mirror are each equal to or more than 20 mm and equal to or less than 100 mm.

20. An electronic device manufacturing method, comprising:
generating pulse laser light using a gas laser device;
outputting the pulse laser light to an exposure apparatus; and
exposing a photosensitive substrate to the pulse laser light in the exposure apparatus to manufacture an electronic device,
the gas laser device including:
a laser oscillator configured to output the pulse laser light having an ultraviolet wavelength;
a laser amplifier configured to amplify the pulse laser light output from the laser oscillator, and including an optical resonator including an output coupling mirror configured to output the amplified pulse laser light, and a laser chamber arranged on an optical path of the optical resonator and including a pair of discharge electrodes;
a first beam expander arranged downstream of the laser chamber in an output direction of the pulse laser light and configured to expand a beam width of the pulse laser light output from the laser chamber;
a second beam expander configured to further expand the beam width of the pulse laser light output from the first beam expander; and
an optical pulse stretcher configured to extend a pulse width of the pulse laser light output from the second beam expander.
